(19) United States
(12) Patent Application Publication
(10) Pub. No.: US 2024/0295595 A1
(43) Pub. Date: Sep. 5, 2024

(54) SPACE SPECTRUM ESTIMATION METHOD OF SUPER-RESOLUTION COPRIME PLANAR ARRAY BASED ON TENSOR FILLING OF OPTIMAL STRUCTURED VIRTUAL DOMAIN

(71) Applicant: Zhejiang University, Zhejiang (CN)

(72) Inventors: Zhiguo SHI, Zhejiang (CN); Hang ZHENG, Zhejiang (CN); Jiming CHEN, Zhejiang (CN); Chengwei ZHOU, Zhejiang (CN); Yong WANG, Zhejiang (CN)

(73) Assignee: Zhejiang University, Zhejiang (CN)

(21) Appl. No.: 18/022,990

(22) PCT Filed: Feb. 16, 2022
(86) PCT No.: PCT/CN2022/076432

§ 371 Date: Feb. 24, 2023

(30) Foreign Application Priority Data
Jan. 21, 2022 (CN) 202210076321.4

(51) Int. Cl. G01R 29/08

(52) U.S. Cl. CPC G01R 29/0892

(57) ABSTRACT

Disclosed in the present invention is a space spectrum estimation method of a super-resolution coprime planar array based on tensor filling of an optimal structured virtual domain, which mainly solves problems that pieces of missing elements in the virtual domain tensor of the existing method are difficult to be filled effectively. The method includes: modeling a tensor signal of a coprime planar array; deriving an augmented virtual planar array based on a cross-correlation tensor dimension combination; constructing the virtual domain tensor based on a mirror extension of the discontinuous virtual planar array; reconstructing a virtual domain tensor by superposition transformation of virtual domain sub-tensors; obtaining the optimal structured virtual domain tensor based on the dimension optimization of the virtual domain sub-tensors; filling the structured virtual domain tensor based on an alternating direction method of multipliers; and decomposing the filled structured virtual domain tensor to achieve a super-resolution spatial spectrum estimation.

### FIELD OF TECHNOLOGY

The present invention belongs to the technical field of array signal processing, in particular relates to a spatial spectrum estimation technology based on statistical processing based on a sparse array tensor signal, which is specifically a space spectrum estimation method of a super-resolution coprime planar array based on tensor filling of an optimal structured virtual domain, and can be used for target positioning.

### BACKGROUND

Spatial spectrum estimation, as a technique to describe the spatial energy distribution of array signals, is widely used in radar, communications, geological exploration and other fields. At present, the performance requirements on accuracy and resolution of spatial spectrum estimation and so on is constantly improved in increasingly complex application scenarios. Compared with a traditional uniform array, the coprime array, as a typical sparse array architecture with a systematic structure, has the advantages of large aperture and high resolution, which lays a foundation for the breakthrough of spatial spectrum estimation performance. In the scenario of coprime planar array, since a received signal covers three-dimensional spatial features, an original structure of a multi-dimensional signal of the coprime planar array can be preserved by modeling and analyzing the received signal through tensors, so as to mine the multi-dimensional signal features thereof. Based on second-order tensor statistics of the coprime planar array, an augmented multi-dimensional discontinuous virtual array is derived, and a continuous part is extracted therefrom for a virtual domain tensor processing, which can realize the spatial spectrum estimation with Nyquist matching. However, this processing method abandons a large number of discontinuous virtual array elements. Therefore, a serious loss of virtual domain statistics information is caused, resulting in the performance such as the accuracy and resolution of the spatial spectrum estimation is limited.

In the field of image restoration, a low-rank tensor filling technique can fill missing elements randomly distributed in image tensors. However, for the pieces of missing elements in an equivalent virtual domain tensor derived from the coprime planar array, they do not satisfy the premise of random distribution. Therefore, the traditional low-rank filling technique is difficult to fill the virtual domain tensor effectively. Therefore, it is an urgent but challenging technical problem about how to fill the virtual domain tensor with pieces of missing elements, so as to make full use of all the discontinuous virtual domain statistics information of the coprime planar array, and comprehensively improve the performance of spatial spectrum estimation.

### SUMMARY

In view of the difficulty in effectively filling pieces of missing elements in a virtual domain tensor and the limited spatial spectral resolution performance in the existing methods, the purpose of the present invention is to propose a space spectrum estimation method of a super-resolution coprime planar array based on tensor filling of an optimal structured virtual domain. It provides a feasible concept and an effective solution to disperse the pieces of missing elements in the virtual domain tensor to a maximum extent, construct an optimal structured virtual domain tensor, in order to fill the dispersed missing elements effectively and realize the super-resolution coprime planar array space spectrum estimation.

The purpose of this invention is realized through the following technical solutions: a space spectrum estimation method of a super-resolution coprime planar array based on tensor filling of an optimal structured virtual domain, wherein, the method comprises the following steps:
by using 4MₓM_{y}+NₓN_{y}−1 physical antenna array elements, performing construction by a receiving end according to the structure of the coprime planar array, wherein, Mₓ, Nₓ and M_{y}, N_{y} are a pair of coprime integers respectively; the coprime planar array is decomposed into two sparse uniform sub-planar arrays [symbol] ₁ and [symbol] ₂, wherein [symbol] ₁ contains 2Mₓ×2M_{y} antenna array elements, and array element spacings in the x axis direction and the y axis direction are Nₓd and N_{y}d respectively; and [symbol] ₂ contains Nₓ×N_{y} antenna array elements, and array element spacings in the x axis direction and the y axis direction are Mₓd and M_{y}d respectively; the unit interval d is half of the wavelength λ of an incident narrowband signal, i.e. d=λ/2;
assuming there are K far-field narrow-band incoherent signal sources from {(θ₁, φ₁), (θ₂, φ₂), . . . , (θ_{K}, φ_{K})} directions, and θₖ and φₖ are the azimuth and elevation angles of a kth incident signal source respectively, k=1, 2, . . . , K, then T sampling snapshot signals of the sparse uniform sub-planar array [symbol] ₁ can be expressed by a three-dimensional tensor [symbol] ∈ [symbol] ^{2M}^{ₓ}^{×2M}^{_{y}}^{×T} as follows:

$${𝒳}_{{ℙ}_{1}} = {{\sum }^{K}}_{k = 1} {a}_{x}^{( {ℙ}_{1} )} ( {θ}_{k} , {φ}_{k} ) ∘ {a}_{y}^{( {ℙ}_{1} )} ( {θ}_{k} , {φ}_{k} ) ∘ {s}_{k} + {𝒩}_{{ℙ}_{1}} ,$$

wherein, sₖ=[s_{k,1}, s_{k,2}, . . . , s_{k,T}]^{T} is a multi-snapshot sampling signal waveform corresponding to a kth incident signal source, [⋅]^{T} represents a transpose operation, · represents an outer product of the vectors, [symbol] is a noise tensor independent of each signal source, [symbol] (θₖ, φₖ) and [symbol] (θₖ, φₖ) are steering vectors of [symbol] ₁ in x axis direction and y axis direction respectively, and correspond to a signal source with an arrival direction of wave being (θₖ, φₖ), and are expressed as:

$${a}_{x}^{( {ℙ}_{1} )} ( {θ}_{k} , {φ}_{k} ) = {[ 1 , {e}^{- j π {x}_{{ℙ}_{1}}^{( 2 )} {μ}_{k}} , … , {e}^{- j π {x}_{{ℙ}_{1}}^{( 2 {M}_{x} )} {μ}_{k}} ]}^{T} ,$$

$${a}_{y}^{( {ℙ}_{1} )} ( {θ}_{k} , {φ}_{k} ) = {[ 1 , {e}^{- j π {y}_{{ℙ}_{1}}^{( 2 )} {v}_{k}} , … , {e}^{- j π {y}_{{ℙ}_{1}}^{( 2 {M}_{y} )} {v}_{k}} ]}^{T} ,$$

wherein, { [symbol] . . . , [symbol] } . . . { [symbol] . . . , [symbol] } respectively represent the actual positions of physical antenna array elements of sparse uniform sub-planar array [symbol] ₁ in the x axis direction and the y axis direction, and [symbol] =0, [symbol] =0, μₖ=sin(φₖ)cos(θₖ), νₖ=sin(φₖ)sin(θₖ), j=\sqrt{−1};
a received signal of the sparse uniform sub-planar array [symbol] ₂ is represented by another three-dimensional tensor [symbol] ∈ [symbol] ^{N}^{ₓ}^{×N}^{_{y}}^{×T}:

$${𝒳}_{{ℙ}_{2}} = {{\sum }^{K}}_{k = 1} {a}_{x}^{( {ℙ}_{2} )} ( {θ}_{k} , {φ}_{k} ) ∘ {a}_{y}^{( {ℙ}_{2} )} ( {θ}_{k} , {φ}_{k} ) ∘ {s}_{k} + {𝒩}_{{ℙ}_{2}} ,$$

wherein, [symbol] is a noise tensor independent of each signal source, [symbol] (θₖ, φₖ) and [symbol] (θₖ, φₖ) are steering vectors of [symbol] ₂ in x axis direction and y axis direction respectively, and correspond to a signal source with an arrival direction of wave being (θₖ, φₖ), and are expressed as:

$${a}_{x}^{( {ℙ}_{2} )} ( {θ}_{k} , {φ}_{k} ) = {[ 1 , {e}^{- j π {x}_{{ℙ}_{2}}^{( 2 )} {μ}_{k}} , … , {e}^{- j π {x}_{{ℙ}_{2}}^{( {N}_{x} )} {μ}_{k}} ]}^{T} ,$$

$${a}_{y}^{( {ℙ}_{2} )} ( {θ}_{k} , {φ}_{k} ) = {[ 1 , {e}^{- j π {y}_{{ℙ}_{2}}^{( 2 )} {v}_{k}} , … , {e}^{- j π {y}_{{ℙ}_{2}}^{( {N}_{y} )} {v}_{k}} ]}^{T} ,$$

wherein, { [symbol] . . . , [symbol] } and { [symbol] . . . , [symbol] } respectively represent the actual positions of physical antenna array elements of sparse uniform sub-planar array [symbol] ₂ in the x axis direction and the y axis direction, and [symbol] =0, [symbol] =0;
(2) by solving cross-correlation statistics of tensors [symbol] and [symbol] obtaining a second-order cross-correlation tensor [symbol] ∈ [symbol] ^{2M}^{ₓ}^{×2M}^{_{y}}^{×N}^{ₓ}^{×N}^{_{y}}:

$$\begin{matrix}{ℛ}_{{ℙ}_{1} {ℙ}_{2}} = E [ {〈 {𝒳}_{{ℙ}_{1}} , {𝒳}_{{ℙ}_{2}}^{*} 〉}_{3} ] \\ = {\sum }_{k = 1}^{K} {σ}_{k}^{2} {a}_{x}^{( {ℙ}_{1} )} ( {θ}_{k} , {φ}_{k} ) ∘ {a}_{y}^{( {ℙ}_{1} )} ( {θ}_{k} , {φ}_{k} ) ∘ {a}_{x}^{{( {ℙ}_{2} )}^{*}} ( {θ}_{k} , {φ}_{k} ) ∘ \\ {a}_{y}^{{( {ℙ}_{2} )}^{*}} ( {θ}_{k} , {φ}_{k} ) + {𝒩}_{{ℙ}_{1} {ℙ}_{2}}\end{matrix} ,$$

wherein, σₖ²=∈[sₖsₖ^{*}] represents the power of a kth incident signal source, [symbol] =E[< [symbol] >₃] represents a cross-correlation noise tensor, <⋅,⋅>ᵣ represents a tensor contraction operation of two tensors along an rth dimension, E[⋅] represents a mathematical expectation operation, and (⋅)* represents a conjugated operation; defining two dimensional sets [symbol] ={1, 3} and [symbol] ={2, 4}, then a virtual domain signal [symbol] ∈ [symbol] ^{2M}^{ₓ}^{N}^{ₓ}^{×2M}^{_{y}}^{N}^{_{y}} is obtained by combination the dimensions of the cross-correlation tensor [symbol] :

$${U}_{𝕎} {=}^{△} {ℛ}_{{ℙ}_{1} {ℙ}_{{2}_{\{ {𝕁}_{1} , {𝕁}_{2} \}}}} = {\sum }_{k = 1}^{K} {σ}_{k}^{2} {b}_{x} ( k ) ∘ {b}_{y} ( k ) ,$$

wherein, bₓ(k)= [symbol] (θₖ, φₖ)⊗ [symbol] (θₖ, φₖ) and b_{y}(k)= [symbol] (θₖ, φₖ)⊗ [symbol] (θₖ, φₖ) are respectively equivalent to the steering vectors of a discontinuous virtual planar array [symbol] in the x axis direction and y axis direction, corresponding to the signal source of which the arrival direction of wave is (θₖ, φₖ), and ⊗ represents the Kronecker product; the discontinuous virtual planar array [symbol] has the size of [symbol] , and contains the holes of the whole row and the whole column, [symbol] =3MₓNₓ−Mₓ−Nₓ+1, [symbol] =3M_{y}N_{y}−M_{y}−N_{y}+1;
(3) constructing a virtual planar array [symbol] about a coordinate axis mirror of the discontinuous virtual planar array [symbol] and superimposing [symbol] and [symbol] in the third dimension into a three-dimensional discontinuous virtual cubic array [symbol] of size [symbol] , wherein [symbol] = [symbol] = [symbol] , and [symbol] =2; rearranging elements in a conjugate transpose signal U [symbol] ^{*} of the virtual domain signal [symbol] to correspond to the position of each virtual element in [symbol] , so as to correspond to a virtual domain signal [symbol] corresponding to the virtual planar array [symbol] ; superimposing [symbol] and [symbol] in the third dimension to obtain a virtual domain tensor [symbol] of the corresponding discontinuous virtual cubic array [symbol] , expressed as:

$${𝒰}_{ℚ} = {\sum }_{k = 1}^{K} {σ}_{k}^{2} {\tilde{b}}_{x} ( k ) ∘ {\tilde{b}}_{y} ( k ) ∘ c ( {μ}_{k} , {v}_{k} ) ,$$

wherein, \tilde{b}ₓ(k) and \tilde{b}_{y}(k) are the steering vectors of the discontinuous virtual cubic array [symbol] in the x axis direction and y axis direction respectively, corresponding to a signal source of which an arrival direction of wave is (θₖ, φₖ), and the elements in \tilde{b}ₓ(k) and \tilde{b}_{y}(k) corresponding to the hole positions in the x axis direction and y axis direction in [symbol] are set to zero respectively,

$$c ( {μ}_{k} , {v}_{k} ) = {[ 1 , {e}^{- j π ( - ( {M}_{x} {M}_{y} + {M}_{x} + {M}_{y} ) {μ}_{k} - ( {N}_{x} {N}_{y} + {N}_{x} + {N}_{y} ) {v}_{k} )} ]}^{T}$$

represents mirror transformation factor vectors corresponding to [symbol] and [symbol] ; since the discontinuous virtual planar array [symbol] contains the whole row and the whole column of holes, the discontinuous virtual cubic array [symbol] obtained by superposition of [symbol] and mirror part [symbol] thereof contains pieces of missing elements, namely holes, so the corresponding virtual domain tensor [symbol] contains pieces of zero elements;
(4) intercepting a virtual domain sub-tensor [symbol] of the virtual domain tensor [symbol] through a translation window with a size of Pₓ×P_{y}×2, wherein [symbol] contains elements of which indexes are respectively (1:Pₓ−1), (1:P_{y}−1), (1:2) in three dimensions of [symbol] ; then, translating the translation window with one element in turn along the x axis direction and the y axis direction respectively, and dividing [symbol] into Lₓ×L_{y} virtual domain sub-tensors, expressed as

$${𝒰}_{{ℚ}_{( {s}_{x} , {s}_{y} )}} ,$$

sₓ=1, 2, . . . , Lₓ, s_{y}=1, 2, . . . , L_{y}; the value range of the translation window size is:

$$2 \leq {P}_{x} \leq {J}_{{ℚ}_{x}} - 1 , \\ 2 \leq {P}_{y} \leq {J}_{{ℚ}_{y}} - 1 ,$$

and Lₓ, L_{y}, Pₓ, P_{y} satisfy the following relation:

$${P}_{x} + {L}_{x} - 1 = {J}_{{ℚ}_{x}} , \\ {P}_{y} + {L}_{y} - 1 = {J}_{{ℚ}_{y}} ,$$

superimposing, in the fourth dimension, the virtual domain sub-tensors

$${𝒰}_{{ℚ}_{( {s}_{x} , {s}_{y} )}}$$

with the same index subscript of s_{y} to obtain L_{y} four-dimensional tensors with dimensions of Pₓ×P_{y}×2×Lₓ; further, superimposing, in the fifth dimension, the L_{y} four-dimensional tensors to obtain a five-dimensional virtual domain tensor [symbol] ∈ [symbol] ^{P}^{ₓ}^{×P}^{_{y}}^{×2×L}^{ₓ}^{×L}^{_{y}} which contains spatial angle information in the x axis direction and the y axis direction, spatial mirror transformation information, and spatial translation information in the x axis direction and the y axis direction; defining dimension sets [symbol] ₁, {1, 2}, [symbol] ₂={3}, [symbol] ₃={4, 5}, and then transforming the virtual domain tensor for dimension combination of [symbol] to obtain a three-dimensional structured virtual domain tensor [symbol] ∈ [symbol] ^{P}^{ₓ}^{P}^{_{y}}^{×L}^{ₓ}^{L}^{_{y}}^{×2}.

$${𝒦}_{ℚ} {=}^{△} {𝒯}_{{ℚ}_{\{ {𝕂}_{1} , {𝕂}_{2} , {𝕂}_{3} \}}} ,$$

the three dimensions of [symbol] respectively represent the spatial angle information, spatial translation information, and spatial mirror transformation information; therefore, pieces of missing elements in the virtual domain tensor [symbol] are randomly distributed to the three spatial dimensions contained by the structured virtual domain tensor [symbol] ;
(5) since the dispersion degree and proportion of the zero elements in the structured virtual domain tensor [symbol] are closely related to the effect of tensor filling, in order to ensure the maximum dispersion degree and minimum proportion of the zero elements in [symbol] , optimizing the dimension size of the virtual domain sub-tensor, that is, optimizing and selecting the value of (Pₓ, P_{y}), so as to obtain an optimal structured virtual domain tensor, wherein the specific process is as follows: according to each value combination (Pₓ, P_{y}), calculating the sum of Euclidean distances of each two zero elements in the corresponding structured virtual domain tensor [symbol] :

$$ψ = {\sum }_{{ζ}_{{z}_{1}} , {ζ}_{{z}_{1}} ∈ Ω , {ζ}_{{z}_{1}} \neq {ζ}_{{z}_{1}}} {‖ {ζ}_{{z}_{1}} - {ζ}_{{z}_{2}} ‖}_{2} ,$$

wherein, Ω represents a position index set of zero elements in [symbol] , ζ_{z}_{₁} and ζ_{z}_{₂} represent the coordinates of any two positions in the set Ω, wherein, z₁, z₂=1, 2, . . . , [symbol] [symbol] represents the total number of zero elements in [symbol] ; the dispersion degree of zero elements in the structured virtual domain tensor [symbol] is determined by parameter ψ; correspondingly, expressing the proportion of zero elements in the structured virtual domain tensor [symbol] as:

$${z}_{} = \frac{{Z}_{{𝒦}_{ℚ}}}{2 {P}_{x} {P}_{y} {L}_{x} {L}_{y}} ,$$

comprehensively considering maximizing the dispersion degree of zero elements in the [symbol] structured virtual domain tensor and minimizing the proportion of zero elements [symbol] _{z}, expressing a dimension optimization problem of the virtual domain sub-tensor as:

$${min}_{{P}_{x} , {P}_{y}} ψ / {z}_{} \\ s . t . 2 \leq {P}_{x} \leq {J}_{{ℚ}_{x}} - 1 , \\ 2 \leq {P}_{y} \leq {J}_{{ℚ}_{y}} - 1 ,$$

traversing all values within the value range [2, [symbol] −1] and [2, [symbol] −1] of Pₓ and P_{y}, the values of each group (Pₓ, P_{y}) correspond to the values of a group (Pₓ, P_{y}) corresponding to the objective function value ψ/ [symbol] _{z}, which is selected as the maximum value of the target function, that is, the dimension size of the optimal virtual domain sub-tensor

$${𝒰}_{{ℚ}_{( {s}_{x} , {s}_{y} )}} ;$$

(6) designing a structured virtual domain tensor filling optimization problem based on an alternating direction method of multipliers:

$${min}_{{\overline{𝒦}}_{\overline{ℚ}} , {𝒴}_{b}} {\sum }_{b = 1}^{3} {α}_{b} {‖ {[ {\overline{𝒦}}_{\overline{ℚ}} ]}_{( b )} ‖}_{*} \\ s . t . {𝒫}_{\overline{Ω}} ( {\overline{𝒦}}_{\overline{ℚ}} ) = {𝒫}_{\overline{Ω}} ( {𝒦}_{ℚ} ) , \\ {𝒴}_{b} - {\overline{𝒦}}_{\overline{ℚ}} = 𝒪 ,$$

wherein, the optimization variable [symbol] ∈ [symbol] ^{P}^{ₓ}^{P}^{_{y}}^{×L}^{ₓ}^{L}^{_{y}}^{×2} is the filled structured virtual domain tensor, corresponding to a virtual uniform cubic array [symbol] ; [ [symbol] ]_{(b)} represents a matrix expanded by [symbol] along the bth dimension; α_{b} is a kernel norm weight constant, which needs to meet α₁+α₂+α₃=1; ∥⋅∥_{*} represents the kernel norm; in order to ensure that the kernel norms [ [symbol] ]_{(b)} of the three matrices of [symbol] can be optimized independently, the three auxiliary tensors [symbol] _{b}= [symbol] , b=1, 2, 3 of [symbol] are introduced in this problem; Ω̅ represents the position index set of non-zero elements in [symbol] ; [symbol] _{Ω̅}(⋅) represents the mapping of the tensor on Ω̅; [symbol] represents the zero tensor; introducing a dual variable [symbol] _{b}, b=1, 2, 3 of [symbol] _{b}, then the Lagrange function of the above optimization problem can be expressed as:

$$ℒ ( {\overline{𝒦}}_{\overline{ℚ}} , {𝒴}_{b} , {ℳ}_{b} ) = {‖ {\overline{𝒦}}_{\overline{ℚ}} ‖}_{*} + [ {𝒴}_{b} - {\overline{𝒦}}_{\overline{ℚ}} \times {ℳ}_{b} ] + \frac{ρ}{2} {‖ {𝒴}_{b} - {\overline{𝒦}}_{\overline{ℚ}} ‖}_{F}^{2} ,$$

wherein, p>0 is a compensation factor, [⋅X⋅] is a tensor inner product, ∥⋅∥_{F} represents the Frobenius norm; iteratively solving a target variable [symbol] , [symbol] _{b} by minimizing the Lagrange function, so as to obtain the filled structured virtual domain tensor [symbol] ;
(7) theoretical modeling the filled structured virtual domain tensor [symbol] as:

$${\overline{𝒦}}_{\overline{ℚ}} = {\sum }_{k = 1}^{K} {σ}_{k}^{2} p ( {μ}_{k} , {v}_{k} ) ∘ q ( {μ}_{k} , {v}_{k} ) ∘ c ( {μ}_{k} , {v}_{k} ) ,$$

wherein, p(μk, νₖ)=dₓ(μₖ)⊗d_{y}(νₖ), q(μₖ, νₖ)=gₓ(μₖ)⊗g_{y}(νₖ) are spatial factors of [symbol] ,

$${d}_{x} ( {μ}_{k} ) = {[ {e}^{- j π ( - {M}_{x} {N}_{x} + {M}_{x} ) {μ}_{k}} , {e}^{- j π ( - {M}_{x} {N}_{x} + {M}_{x} + 1 ) {μ}_{k}} , … , {e}^{- j π ( 2 {M}_{x} {N}_{x} - {N}_{x} ) {μ}_{k}} ]}^{T} ,$$

$${d}_{y} ( {v}_{k} ) = {[ {e}^{- j π ( - {M}_{y} {N}_{y} + {M}_{y} ) {v}_{k}} , {e}^{- j π ( - {M}_{y} {N}_{y} + {M}_{y} + 1 ) {v}_{k}} , … , {e}^{- j π ( 2 {M}_{y} {N}_{y} - {N}_{y} ) {v}_{k}} ]}^{T} ,$$

represent the steering vectors of the virtual uniform cubic array [symbol] along the x axis direction and the y axis direction respectively,

$${g}_{x} ( {μ}_{k} ) = {[ 1 , {e}^{- j π {μ}_{k}} , … , {e}^{- j π ( {L}_{x} - 1 ) {μ}_{k}} ]}^{T} ,$$

$${g}_{y} ( {v}_{k} ) = {[ 1 , {e}^{- j π {v}_{k}} , … , {e}^{- j π ( {L}_{y} - 1 ) {v}_{k}} ]}^{T} ,$$

are the spatial translation factor vectors corresponding to the x axis direction and the y axis direction in the process of the translation window intercepting the virtual domain sub-tensor respectively; performing a canonical polyadic decomposition on the filled structured virtual domain tensor [symbol] , so as to obtain the estimated values of three factor vectors p(μₖ, νₖ), q(μₖ, νₖ) and c(μₖ, νₖ), representing as \hat{p}(μₖ, νₖ), \hat{q}(μₖ, νₖ) and ĉ(μₖ, νₖ); constructing a structured virtual domain tensor signal sub-space Vₛ ∈ [symbol] ^{2P}^{ₓ}^{P}^{_{y}}^{L}^{ₓ}^{L}^{_{y}}^{×K}.

$${V}_{s} = orth ( [ \hat{p} ( {μ}_{1} , {v}_{1} ) ⊗ \hat{q} ( {μ}_{1} , {v}_{1} ) ⊗ \hat{c} ( {μ}_{1} , {v}_{1} ) , \hat{p} ( {μ}_{2} , {v}_{2} ) ⊗ \hat{q} ( {μ}_{2} , {v}_{2} ) ⊗ \hat{c} ( {μ}_{2} , {v}_{2} ) , … ,$$

$$\hat{p} ( {μ}_{K} , {v}_{K} ) ⊗ \hat{q} ( {μ}_{K} , {v}_{K} ) ⊗ \hat{c} ( {μ}_{K} , {v}_{K} ) ] ) ,$$

wherein, orth(⋅) represents a matrix orthogonalization operation; representing the noise sub-space as Vⁿ ∈ [symbol] ^{2P}^{ₓ}^{P}^{_{y}}^{L}^{ₓ}^{L}^{_{y}}^{×(2P}^{ₓ}^{P}^{_{y}}^{L}^{ₓ}^{L}^{_{y}}^{-K}), whereby VₙVₙ^{H} is obtained by Vₛ through the following formula:

$${V}_{n} {V}_{n}^{H} = 1 - {V}_{s} {V}_{s}^{H} ,$$

wherein, I represents the identity matrix, (⋅)^{H} represents a conjugate transpose operation;
traversing the two-dimensional arrival direction of wave (θ, φ), wherein θ and φ are respectively the azimuth angle and elevation angle traversed within the value range of [−90°, 90°] and [0°, 180° ], calculating the corresponding parameters μk=sin (φₖ) cos (θₖ), νₖ=sin(φₖ)sin(θₖ), and constructing the steering vector [symbol] (μₖ, νₖ) ∈ [symbol] ^{2P}^{ₓ}^{P}^{_{y}}^{L}^{ₓ}^{L}^{_{y}} corresponding to the virtual uniform cubic array [symbol] , expressed as:

$$( {μ}_{k} , {v}_{k} ) = \hat{p} ( {μ}_{k} , {v}_{k} ) ⊗ \hat{q} ( {μ}_{k} {v}_{k} ) ⊗ \hat{c} ( {μ}_{k} , {v}_{k} ) ,$$

obtaining the spatial spectrum [symbol] (θ, φ) corresponding to the two-dimensional arrival direction of wave (θ, φ) as follows:

$$𝒫 ( θ , φ ) = 1 / ( {H}^{} ( {μ}_{k} , {v}_{k} ) ( {V}_{n} {V}_{n}^{H} ) ( {μ}_{k} , {v}_{k} ) ) .$$

Further, the structure of coprime planar array described in step (1) is specifically described as follows: constructing a pair of sparse uniform sub-planar arrays [symbol] ₁ and [symbol] ₂ on the plane coordinate system xoy, wherein [symbol] ₁ contains 2Mₓ×2M_{y} antenna array elements, the array element spacings in the x axis direction and the y axis direction are Nₓd and N_{y}d respectively, and the position coordinate thereof on xoy is {(Nₓdmₓ, N_{y}dm_{y}), mₓ=0, 1, . . . , 2Mₓ−1, m_{y}=0, 1, . . . , 2M_{y}−1}; [symbol] ₂ contains Nₓ×N_{y} antenna array elements, the array spacings in the x axis direction and the y axis direction are Mₓd and M_{y}d respectively, and the position coordinate thereof on xoy is {(Mₓdnₓ, M_{y}dn_{y}), nₓ=0,1, . . . , Nₓ−1, n_{y}=0, 1, . . . , N_{y}−1}; Mₓ, Nₓ and M_{y}, N_{y} are a pair of reciprocal integers, respectively; performing a sub-array combination on [symbol] ₁ and [symbol] ₂ in the way of overlapping the array elements in (0, 0) position in the coordinate system, whereby a coprime planar array containing 4MₓM_{y}+NₓN_{y}−1 physical antenna array elements is obtained.

Further, in the cross-correlation tensor deduction described in step (2), in practice, [symbol] is obtained by estimating the cross-correlation statistics of the tensors [symbol] and [symbol] namely, sampling the cross-correlation tensor [symbol] ∈ [symbol] ^{2M}^{ₓ}^{×2M}^{_{y}}^{×N}^{ₓ}^{×N}^{_{y}}:

$${\hat{ℛ}}_{{ℙ}_{1} {ℙ}_{2}} = \frac{1}{T} < {𝒳}_{{ℙ}_{1}} , {𝒳}_{{ℙ}_{2}}^{*} {>}_{3} .$$

Further, in step (6), the target variables [symbol] , [symbol] _{b} are iteratively solved by minimizing the Lagrange function [symbol] ( [symbol] , [symbol] _{b}, [symbol] _{b}); in the η+1 th iteration, [symbol] , [symbol] _{b} and [symbol] _{b} are updated as:

$${𝒴}_{b}^{( η + 1 )} = {argmin}_{{𝒴}_{b}} ℒ ( {\overline{𝒦}}_{\overline{ℚ}}^{( η )} , {𝒴}_{b} , {ℳ}_{b}^{( η )} ) ,$$

$${\overline{𝒦}}_{\overline{ℚ}}^{( η + 1 )} = {argmin}_{{\overline{𝒦}}_{\overline{ℚ}}} ℒ ( {\overline{𝒦}}_{\overline{ℚ}} , {𝒴}_{b}^{( η + 1 )} , {ℳ}_{b}^{( η )} ) ,$$

$${ℳ}_{b}^{( η + 1 )} = {ℳ}_{b}^{( η )} - ρ ( {𝒴}_{b}^{( η + 1 )} - {\overline{𝒦}}_{\overline{ℚ}}^{( η + 1 )} ) ,$$

a closed-form solution for the target variables [symbol] , [symbol] _{b} are as follows:

$${𝒴}_{b}^{( η + 1 )} = {fold}_{( b )} [ {Γ}_{\frac{{α}_{b}}{ρ}} ( {[ {\overline{𝒦}}_{\overline{ℚ}}^{( η )} ]}_{( b )} + {\frac{1}{ρ} [ {ℳ}_{b}^{( η + 1 )} ]}_{( b )} ) ] ,$$

$${𝒫}_{Ω} ( {\overline{𝒦}}_{\overline{ℚ}}^{( η + 1 )} ) = {𝒫}_{Ω} ( \frac{1}{3} ( {\sum }_{b = 1}^{3} {𝒴}_{b}^{( η + 1 )} - \frac{1}{ρ} {ℳ}_{b}^{( η )} ) ) ,$$

wherein,

$${Γ}_{\frac{{α}_{b}}{ρ}} ( X ) = {U}_{X} {\sum }_{( \frac{{α}_{b}}{ρ} )} {V}_{X}$$

represents a threshold singular value decomposition operation of matrix X∈ [symbol] ^{X}^{₁}^{×X}^{₂},

$${\sum }_{( \frac{{α}_{b}}{ρ} )} = diag ( max ( {\overline{ω}}_{1} - \frac{{α}_{b}}{ρ} , 0 ) ) ,$$

ω̅₁, 1=1, 2, . . . , min (X₁, X₂) represents the singular value of X, Uₓ, Vₓ represent the left and right singular matrices of X, fold_{(b)}[⋅] represents an inverse operation of tensor expansion [⋅]_{(b)}, diag(c) represents a diagonal matrix with the elements in the vector c as diagonal elements, max(⋅) represents a maximum operation, min(⋅) represents a minimum operation.

Compared with the prior art, the present invention has the following advantages:

(1) The present invention designs the optimal reconstruction criterion of the virtual domain tensor, constructs the structured virtual domain tensor by maximizing the dispersion degree of missing elements in the virtual domain tensor, and lays a foundation for effectively filling the virtual domain tensor with pieces of missing elements.

(2) The present invention proposes a structured virtual domain tensor filling method based on an alternating direction method of multipliers, which makes full use of all the discontinuous virtual domain statistics information of the coprime planar array, and thus realizes the super-resolution spatial spectrum estimation for the coprime planar array under the condition of Nyquist matching.

### BRIEF DESCRIPTION OF THE DRAWINGS

FIG. 1 is a general flow block diagram of the present invention.

FIG. 2 is a schematic structural diagram of a coprime planar array constructed by the present invention.

FIG. 3 is a schematic diagram of a discontinuous virtual cubic array constructed by the present invention.

FIG. 4 is a schematic diagram of a sub-tensor interception process of a virtual domain designed by the present invention.

FIG. 5 is a spatial spectrum estimation effect diagram of the method proposed by the present invention.

### DESCRIPTION OF THE EMBODIMENTS

The technical solutions of the present invention will be described in further detail below with reference to the accompanying drawings.

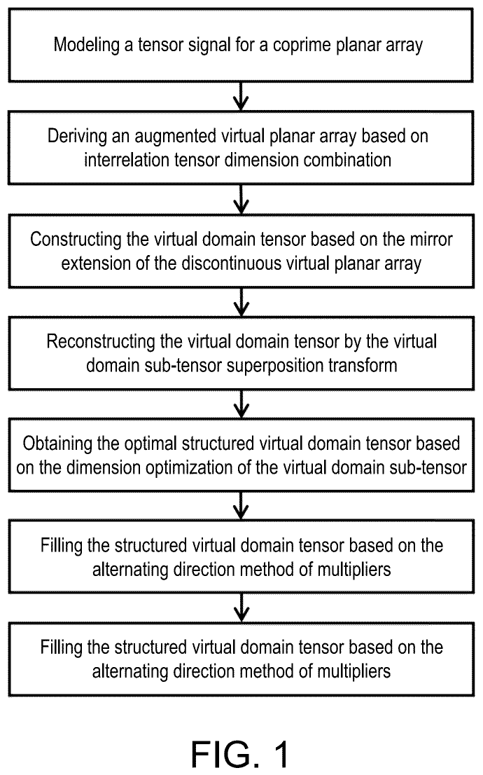

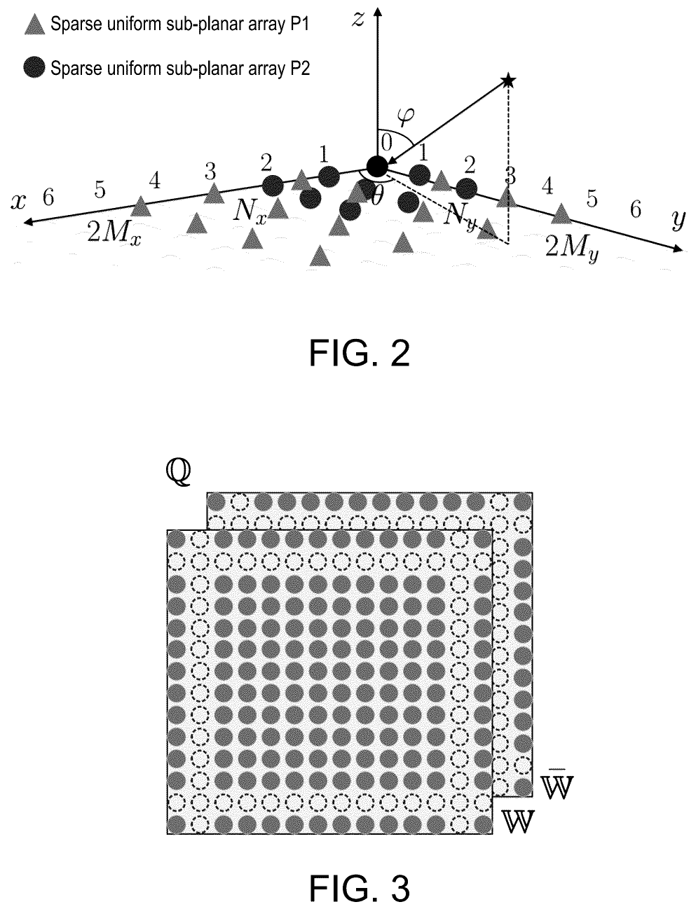

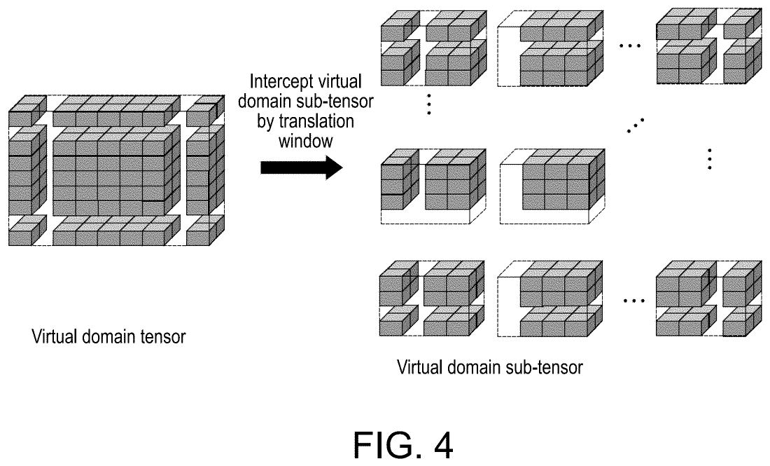

In view of the difficulty in effectively filling pieces of missing elements in a virtual domain tensor and the limited spatial spectral resolution performance in the existing methods, the present invention proposes a space spectrum estimation method of a super-resolution coprime planar array based on tensor filling of an optimal structured virtual domain. By means of an optimal reconstruction criterion of the virtual domain tensor and an alternating direction method of multipliers, the pieces of missing elements in the virtual domain tensor are filled effectively to achieve the super-resolution space spectrum estimation of the coprime planar array. Referring to FIG. 1, the implementation steps of the present invention are as follows:
Step 1: modeling a tensor signal for a coprime planar array. At a receiving end, using 4MₓM_{y}+NₓN_{y}−1 physical antenna array elements to construct a coprime planar array. As shown in FIG. 2, constructing a pair of sparse uniform sub-planar arrays [symbol] ₁ and [symbol] ₂ on a plane coordinate system xoy, wherein [symbol] ₁ contains 2Mₓ×2M_{y} antenna array elements, the array element spacings in the x axis direction and the y axis direction are Nₓd and N_{y}d respectively, and the position coordinate thereof on xoy is {(Nₓdmₓ), N_{y}dm_{y}, mₓ=0, 1, . . . , 2Mₓ−1}; [symbol] ₂ contains Nₓ×N_{y} antenna array elements, the array spacings in the x axis direction and the y axis direction are Mₓd and M_{y}d respectively, and the position coordinate thereof on xoy is {(Mₓdnₓ, M_{y}dn_{y}), nₓ=0, 1, . . . , Nₓ−1, . . . , N_{y}−1}; Mₓ, Nₓ and M_{y}, N_{y} are a pair of reciprocal integers, respectively; a unit interval d is taken as half of the wavelength of the incident narrow-band signal λ, that is, d=λ/2; performing a sub-array combination on MₓM_{y} and a in the way of overlapping the array elements in d=λ/2 position in the coordinate system, whereby a coprime planar array containing 4MₓM_{y}+NₓN_{y}−1 physical antenna array elements is obtained.

Assuming that there are K far-field narrow-band non-correlated signal sources from {(θ1, φ₁), (θ₂, φ₂), . . . , (θ_{K}, θ_{K})} direction, superimposing, in the third dimension, T sampling snapshot signals of sparse uniform sub-planar array [symbol] 1 in the coprime planar array, so as to obtain a three-dimensional tensor signal [symbol] ∈ [symbol] ^{2M}^{ₓ}^{×2M}^{_{y}}^{×T}, which can be modeled as:

$${𝒳}_{{ℙ}_{1}} = {\sum }_{k = 1}^{K} {a}_{x}^{( {ℙ}_{1} )} ( {θ}_{k} , {φ}_{k} ) ∘ {a}_{y}^{( {ℙ}_{1} )} ( {θ}_{k} , {φ}_{k} ) ∘ {s}_{k} + {𝒩}_{{ℙ}_{1}} ,$$

wherein, Sₖ=[S_{k,1}, S_{k,2}, . . . , S_{k,T}]^{T} is a multi-snapshot sampling signal waveform corresponding to a kth incident signal source, [⋅]^{T} represents a transpose operation, · represents an outer product of the vectors, [symbol] is a noise tensor independent of each signal source, [symbol] (θₖ, φₖ) and [symbol] (θₖ, φₖ) are steering vectors of [symbol] ₁ in x axis direction and y axis direction respectively, and correspond to a signal source with an arrival direction of wave being (θₖ, φₖ), and are expressed as:

$${a}_{x}^{( {ℙ}_{1} )} ( {θ}_{k} , {φ}_{k} ) = {[ 1 , {e}^{- j π {x}_{{ℙ}_{1}}^{( 2 )} {μ}_{k}} , … , {e}^{- j π {x}_{{ℙ}_{1}}^{( 2 {M}_{x} )} {μ}_{k}} ]}^{T} ,$$

$${a}_{y}^{( {ℙ}_{1} )} ( {θ}_{k} , {φ}_{k} ) = {[ 1 , {e}^{- j π {y}_{{ℙ}_{1}}^{( 2 )} {v}_{k}} , … , {e}^{- j π {y}_{{ℙ}_{1}}^{( 2 {M}_{y} )} {v}_{k}} ]}^{T} ,$$

wherein, { [symbol] . . . , [symbol] } and { [symbol] . . . , [symbol] } respectively represent the actual positions of physical antenna array elements of the sparse uniform sub-planar array [symbol] ₁ in the x axis direction and the y axis direction, and [symbol] =0, [symbol] =0, μₖ=sin(φₖ)cos(θₖ), νₖ=sin(φₖ)sin(θₖ), j=\sqrt{−1}. Similarly, the T sampling snapshot signals of sparse uniform sub-planar array [symbol] ₂ can be represented by another three-dimensional tensor [symbol] ∈ [symbol] ^{N}^{ₓ}^{×N}^{_{y}}^{×T}.

$${X}_{{ℙ}_{2}} = {\sum }_{k = 1}^{K} {a}_{x}^{( {ℙ}_{2} )} ( {θ}_{k} , {φ}_{k} ) ∘ {a}_{y}^{( {ℙ}_{2} )} ( {θ}_{k} , {φ}_{k} ) ∘ {s}_{k} + {𝒩}_{{ℙ}_{2}} ,$$

wherein, [symbol] is a noise tensor independent of each signal source, [symbol] (θₖ, φₖ) and [symbol] (θₖ, φₖ) are steering vectors of [symbol] ₂ in x axis direction and y axis direction respectively, and correspond to a signal source with an arrival direction of wave being (θₖ, φₖ), and are expressed as:

$${a}_{x}^{( {ℙ}_{2} )} ( {θ}_{k} , {φ}_{k} ) = {[ 1 , {e}^{- j π {x}_{{ℙ}_{2}}^{( 2 )} {μ}_{k}} , … , {e}^{- j π {x}_{{ℙ}_{2}}^{( {N}_{x} )} {μ}_{k}} ]}^{T} ,$$

$${a}_{y}^{( {ℙ}_{2} )} ( {θ}_{k} , {φ}_{k} ) = {[ 1 , {e}^{- j π {y}_{{ℙ}_{2}}^{( 2 )} {v}_{k}} , … , {e}^{- j π {y}_{{ℙ}_{2}}^{( {N}_{y} )} {v}_{k}} ]}^{T} ,$$

wherein, { [symbol] . . . , [symbol] } and { [symbol] . . . , [symbol] } respectively represent the actual positions of physical antenna array elements of sparse uniform sub-planar array [symbol] ₂ in the x axis direction and the y axis direction, and [symbol] =0, [symbol] =0;
Step 2: deriving an augmented virtual planar array based on interrelation tensor dimension combination. By solving cross-correlation statistics of tensor signals [symbol] , and [symbol] , obtaining a second-order cross-correlation tensor [symbol] ∈ [symbol] ^{2M}^{ₓ}^{×2M}^{_{y}}^{×N}^{ₓ}^{×N}^{_{y}}.

$${ℛ}_{{ℙ}_{1} {ℙ}_{2}} = E [ < {𝒳}_{{ℙ}_{1}} , {𝒳}_{{ℙ}_{2}}^{*} > ] = {\sum }_{k = 1}^{K} {σ}_{k}^{2} {a}_{x}^{( {ℙ}_{1} )} ( {θ}_{k} , {φ}_{k} ) ∘ {a}_{y}^{( {ℙ}_{1} )} ( {θ}_{k} , {φ}_{k} ) ∘ {a}_{x}^{{( {ℙ}_{2} )}^{*}} ( {θ}_{k} , {φ}_{k} ) ∘ {a}_{y}^{{( {ℙ}_{2} )}^{*}} ( {θ}_{k} , {φ}_{k} ) + {𝒩}_{{ℙ}_{1} {ℙ}_{2}} ,$$

wherein, σₖ²=E[sₖsₖ] represents the power of a kth incident signal source, [symbol] =E[< [symbol] >₃] represents a cross-correlation noise tensor, <⋅, ⋅>ᵣ represents a tensor contraction operation of two tensors along an rth dimension, E[⋅] represents a mathematical expectation operation, and (⋅)* represents a conjugated operation. In practice, [symbol] is obtained by estimating the cross-correlation statistics of the tensor signals [symbol] and [symbol] , namely, sampling the cross-correlation tensor [symbol] ∈ [symbol] ^{2M}^{ₓ}^{×2M}^{_{y}}^{×N}^{ₓ}^{×N}^{_{y}}:

$${\hat{ℛ}}_{{ℙ}_{1} {ℙ}_{2}} = \frac{1}{T} < {𝒳}_{{ℙ}_{1}} , {𝒳}_{{ℙ}_{2}}^{*} {>}_{3} ,$$

By combination the dimensions representing spatial information in the same direction in the cross-correlation tensor [symbol] steering vectors corresponding to two sparse uniform sub-planar arrays can form a difference set array on the exponential term, so as to construct a two-dimensional augmented virtual planar array. Specifically, since the first and third dimensions of the cross-correlation tensor [symbol] represent spatial information of the x axis direction, and the second and fourth dimensions represent spatial information of the y axis direction, the two dimensional sets [symbol] ={1, 3}, [symbol] ={2, 4} of the cross-correlation tensor [symbol] are merged to obtain a virtual domain signal [symbol] ∈ [symbol] ^{2M}^{ₓ}^{N}^{ₓ}^{×2M}^{_{y}}^{N}^{_{y}}:

$${U}_{𝕎} {=}^{Δ} {ℛ}_{{ℙ}_{1} {ℙ}_{{2}_{\{ {𝕁}_{1} , {𝕁}_{2} \}}}} = {\sum }_{k = 1}^{K} {σ}_{k}^{2} {b}_{x} ( k ) ∘ {b}_{y} ( k ) ,$$

wherein, bₓ(k) [symbol] (θₖ, φₖ)⊗ [symbol] (θₖ, φₖ) and b_{y}(k)= [symbol] (θₖ, φₖ)⊗ [symbol] (θₖ, φₖ) are respectively equivalent to the steering vectors of a discontinuous virtual planar array [symbol] in the x axis direction and y axis direction, corresponding to a signal source of which the arrival direction of wave is (θₖ, φₖ), and ⊗ represents the Kronecker product. The discontinuous virtual planar array [symbol] has the size of [symbol] , and contains the holes of the whole row and the whole column, [symbol] =3MₓNₓ−Mₓ−Nₓ+1, [symbol] =3M_{y}N_{y}−M_{y}−N_{y}+1. Here, in order to simplify the derivation process, the cross-correlation noise tensor [symbol] is omitted from the theoretical modeling step of [symbol] ; however, in practice, because the sampling cross-correlation tensor [symbol] is used instead of the theoretical cross-correlation tensor [symbol] , [symbol] is still contained in the statistical processing of virtual domain signal;
Step 3: constructing the virtual domain tensor based on the mirror extension of the discontinuous virtual planar array. Extending the virtual planar array [symbol] of discontinuous virtual planar array [symbol] about the coordinate axis mirror, and superimposing [symbol] and [symbol] in the third dimension into a three-dimensional discontinuous virtual cubic array [symbol] of size [symbol] , as shown in FIG. 3. Here, [symbol] = [symbol] = [symbol] , and [symbol] =2. Rearranging the elements in the conjugate transpose signal U_{w}^{*} of the virtual domain signal U_{w} to correspond to the position of each virtual array element in [symbol] , so as to obtain the virtual domain signal [symbol] corresponding to the discontinuous virtual planar array [symbol] ; superimposing [symbol] and [symbol] on the third dimension to obtain the virtual domain tensor [symbol] of the corresponding discontinuous virtual cubic array [symbol] expressed as:

$${𝒰}_{ℚ} = {\sum }_{k = 1}^{K} {σ}_{k}^{2} {\tilde{b}}_{x} ( k ) ∘ {\tilde{b}}_{y} ( k ) ∘ c ( {μ}_{k} , {v}_{k} ) ,$$

wherein, \tilde{b}ₓ(k) and \tilde{b}_{y}(k) are the steering vectors of the discontinuous virtual cubic array [symbol] in the x axis direction and y axis direction respectively, corresponding to a signal source of which an arrival direction of wave is (θₖ, φₖ), and the elements in \tilde{b}ₓ(k) and \tilde{b}_{y}(k) corresponding to the hole positions in the x axis direction and y axis direction in [symbol] are set to zero respectively,

$$c ( {μ}_{k} , {v}_{k} ) = {[ 1 , {e}^{- j π ( - ( {M}_{x} {M}_{y} + {M}_{x} + {M}_{y} ) {μ}_{k} - ( {N}_{x} {N}_{y} + {N}_{x} + {N}_{y} ) {v}_{k} )} ]}^{T}$$

represents mirror transformation factor vectors corresponding to [symbol] and [symbol] ; since the discontinuous virtual planar array [symbol] contains the whole row and the whole column of holes, the discontinuous virtual cubic array [symbol] obtained by superposition of [symbol] and mirror part [symbol] thereof contains pieces of missing elements (namely holes), so the corresponding virtual domain tensor [symbol] contains pieces of zero elements;
Step 4: reconstructing the virtual domain tensor by the virtual domain sub-tensor superposition transform. In order to realize Nyquist matched signal processing on a virtual uniform cubic array, the missing elements in the virtual domain tensor [symbol] need to be filled to correspond to a virtual uniform cubic array [symbol] because the coprime array does not satisfy the Nyquist sampling theorem. However, existing tensor filling techniques based on the low-rank criterion are based on a random distribution of missing elements in the tensor, so it is unable to effectively fill the virtual domain tensor [symbol] with pieces of missing elements. Therefore, it is necessary to reconstruct the virtual domain tensor [symbol] to disperse its pieces of missing elements. The specific process is as follows: designing a translation window with a size of Pₓ×P_{y}×2 to intercept a virtual domain sub-tensor [symbol] of the virtual domain tensor [symbol] , wherein [symbol] contains elements of which indexes are respectively (1:Pₓ−1), (1:P_{y}−1), (1:2) in three dimensions of [symbol] ; then, translating the translation window with one element in turn along the x axis direction and the y axis direction respectively, and dividing [symbol] into Lₓ×L_{y} virtual domain

$${𝒰}_{{ℚ}_{( {s}_{x} , {s}_{y} )}} ,$$

value range of the translation window size is:

$$2 \leq {P}_{x} \leq {J}_{{ℚ}_{x}} - 1 ,$$

$$2 \leq {P}_{y} \leq {J}_{{ℚ}_{y}} - 1 ,$$

and Lₓ, L_{y}, Pₓ, P_{y} satisfy the following relation:

$${P}_{x} + {L}_{x} - 1 = {J}_{{ℚ}_{x}} ,$$

$${P}_{y} + {L}_{y} - 1 = {J}_{{ℚ}_{y}} ,$$

Superimposing the virtual domain sub-tensors

$${𝒰}_{{ℚ}_{( {s}_{x} , {s}_{y} )}}$$

with the same s_{y} index subscript in the fourth dimension to obtain L_{y} four-dimensional tensors with dimensions of Pₓ×P_{y}×2×Lₓ; further, superimposing the L_{y} four-dimensional tensors in the fifth dimension to obtain a five-dimensional virtual domain tensor [symbol] ∈ [symbol] ^{P}^{ₓ}^{×P}^{_{y}}^{×2×L}^{ₓ}^{×L}^{_{y}}. The five-dimensional virtual domain tensor [symbol] comprises the spatial angle information in the x axis direction and the y axis direction, the spatial mirror transformation information, and the spatial translation information in the x axis direction and the y axis direction. [symbol] are combined along the first and second dimensions representing the spatial angle information, and are combined along the fourth and fifth dimensions representing the spatial translation information, and the third dimension representing the spatial image transformation information is retained to construct the structured virtual domain tensor. The specific operation is as follows: defining dimension sets [symbol] ₁={1, 2}, [symbol] ₂={3}, [symbol] ₃={4, 5}, then performing the virtual domain tensor transformation for dimension combination on [symbol] to obtain the three-dimensional structured virtual domain tensor [symbol] ∈ [symbol] ^{P}^{ₓ}^{P}^{_{y}}^{×L}^{ₓ}^{L}^{_{y}}^{×2}.

$${𝒦}_{ℚ} {=}^{Δ} {𝒯}_{{ℚ}_{{\{ {𝕂}_{1} , {𝕂}_{2} , {𝕂}_{3} \}}^{′}}}$$

The three dimensions of [symbol] , respectively, represent the spatial angle information, spatial translation information and spatial mirror transformation information. Therefore, pieces of missing elements in the virtual domain tensor [symbol] are randomly distributed to the three spatial dimensions contained by the structured virtual domain tensor [symbol] ;
Step 5: obtaining the optimal structured virtual domain tensor based on the dimension optimization of the virtual domain sub-tensor. In the process of reconstruction of the virtual domain tensor, the size of the translation window, namely the dimension size (Pₓ, P_{y}) of the virtual domain sub-tensor

$${𝒰}_{{ℚ}_{( {s}_{x} , {s}_{y} )}} ,$$

would affect the dispersion degree and proportion of zero elements in the structured virtual domain tensor [symbol] , and the above two indexes are closely related to the effect of tensor filling. In order to ensure the maximum dispersion degree and minimum proportion of the zero elements in [symbol] , optimizing the dimension size of the virtual domain sub-tensor, that is, optimizing and selecting the value of (Pₓ, P_{y}), so as to obtain an optimal structured virtual domain tensor, wherein the specific process is as follows: according to each value combination (Pₓ, P_{y}), calculating the sum of Euclidean distances of each two zero elements in the corresponding structured virtual domain tensor [symbol] :

$$ψ = {\sum }_{{ζ}_{{z}_{1}} , {ζ}_{{z}_{1}} ∈ Ω , {ζ}_{{z}_{1}} \neq {ζ}_{{z}_{1}}} {‖ {ζ}_{{z}_{1}} - {ζ}_{{z}_{2}} ‖}_{2} ,$$

wherein, Ω represents a position index set of zero elements in [symbol] , (ζ_{z}_{₁} and ζ_{z}_{₂} represent the coordinates of any two positions in the set Ω, wherein, z₁, z₂=1, 2, . . . , [symbol] represents the total number of zero elements in [symbol] . The dispersion degree of zero elements in the structured virtual domain tensor [symbol] is determined by parameter ψ; correspondingly, expressing the proportion of zero elements in the structured virtual domain tensor [symbol] as:

$${z}_{} = {Z}_{{𝒦}_{ℚ}} / 2 {P}_{x} {P}_{y} {L}_{x} {L}_{y} ,$$

comprehensively considering maximizing the dispersion degree of zero elements in the structured virtual domain tensor and minimizing the proportion of zero elements [symbol] _{z}, expressing a dimension optimization problem of the virtual domain sub-tensor as:

$${min}_{{P}_{x} , {P}_{y}} ψ / {z}_{}$$

$$s . t . 2 \leq {P}_{x} \leq {J}_{{ℚ}_{x}} - 1 ,$$

$$2 \leq {P}_{y} \leq {J}_{{ℚ}_{y}} - 1 ,$$

traversing all values within the value range [2, [symbol] -1] and [2, [symbol] -1] of Pₓ and P_{y}, the values of each group (Pₓ, P_{y}) correspond to the values of a group (Pₓ, P_{y}) corresponding to the objective function value ψ/ [symbol] _{z}, which is selected as the maximum value of the target function, that is, the dimension size of the optimal virtual domain sub-tensor

$${𝒰}_{{ℚ}_{( {s}_{x} , {s}_{y} )}} ;$$

Step 6: filling the structured virtual domain tensor based on the alternating direction method of multipliers. Designing a structured virtual domain tensor filling optimization problem based on the Alternating Direction Method of Multipliers (ADMM):

$${min}_{{\overline{𝒦}}_{\overline{ℚ}} , {𝒴}_{b}} {\sum }_{b = 1}^{3} {α}_{b} {‖ {[ {\overline{𝒦}}_{\overline{ℚ}} ]}_{( b )} ‖}_{*} \\ s . t . {𝒫}_{\overline{Ω}} ( {\overline{𝒦}}_{\overline{ℚ}} ) = {𝒫}_{\overline{Ω}} ( {𝒦}_{ℚ} ) , \\ {𝒴}_{b} - {\overline{𝒦}}_{\overline{ℚ}} = 𝒪 ,$$

wherein, the optimization variable [symbol] ∈ [symbol] ^{P}^{ₓ}^{P}^{_{y}}^{×L}^{ₓ}^{L}^{_{y}}^{×2} is the filled structured virtual domain tensor, corresponding to a virtual uniform cubic array [symbol] ; [ [symbol] ]_{(b)} represents a matrix expanded by [symbol] along the bth dimension; α_{b} is a kernel norm weight constant, which needs to meet α₁+α₂+α₃=1; ∥⋅∥_{*} represents the kernel norm; in order to ensure that the kernel norms [ [symbol] ]_{(b)} of the three matrices of [symbol] can be optimized independently, the three auxiliary tensors [symbol] _{b}= [symbol] , 1, 2, 3 of [symbol] are introduced in this problem; Ω̅ represents the position index set of non-zero elements in [symbol] ; [symbol] Ω̅(⋅) represents the mapping of the tensor on Ω̅; [symbol] represents the zero tensor; introducing a dual variable [symbol] _{b}, b=1, 2, 3, then the Lagrange function of the above optimization problem can be expressed as:

$$ℒ ( {\overline{𝒦}}_{\overline{ℚ}} , {𝒴}_{b} , {ℳ}_{b} ) = {‖ {\overline{𝒦}}_{\overline{ℚ}} ‖}_{*} + [ {𝒴}_{b} - {\overline{𝒦}}_{\overline{ℚ}} \times {ℳ}_{b} ] + \frac{ρ}{2} {‖ {𝒴}_{b} - {\overline{𝒦}}_{\overline{ℚ}} ‖}_{F}^{2} ,$$

wherein, ρ>0 is a compensation factor, [⋅x⋅] is a tensor inner product, ∥⋅∥_{F} represents the Frobenius norm. The target variables [symbol] , [symbol] _{b} are iteratively solved b_{y} minimizing the Lagrange function; in the η+1th iteration, [symbol] , [symbol] _{b} and [symbol] _{b} are updated as:

$${𝒴}_{b}^{( η + 1 )} = {arg min}_{{𝒴}_{b}} ℒ ( {\overline{𝒦}}_{\overline{ℚ}}^{( η )} , {𝒴}_{b} , {ℳ}_{b}^{( η )} ) , \\ {\overline{𝒦}}_{\overline{ℚ}}^{( η + 1 )} = {arg min}_{{\overline{𝒦}}_{\overline{ℚ}}} ℒ ( {\overline{𝒦}}_{\overline{ℚ}} , {𝒴}_{b}^{( η + 1 )} , {ℳ}_{b}^{( η )} ) , \\ {ℳ}_{b}^{( η + 1 )} = {ℳ}_{b}^{( η )} - ρ ( {𝒴}_{b}^{( η + 1 )} - {\overline{𝒦}}_{\overline{ℚ}}^{( η + 1 )} ) ,$$

a closed-form solution for the target variables [symbol] , [symbol] _{b} are as follows:

$${𝒴}_{b}^{( η + 1 )} = {fold}_{( b )} [ {Γ}_{\frac{{α}_{b}}{ρ}} ( {[ {\overline{𝒦}}_{\overline{ℚ}}^{( η )} ]}_{( b )} + {\frac{1}{ρ} [ {ℳ}_{b}^{( η + 1 )} ]}_{( b )} ) ] , \\ {𝒫}_{Ω} ( {\overline{𝒦}}_{\overline{ℚ}}^{( η + 1 )} ) = {𝒫}_{Ω} ( \frac{1}{3} ( {\sum }_{b = 1}^{3} {𝒴}_{b}^{( η + 1 )} - \frac{1}{ρ} {ℳ}_{b}^{( η )} ) ) ,$$

wherein,

$${Γ}_{\frac{{α}_{b}}{ρ}} ( X ) = {U}_{X} {Σ}_{( \frac{{α}_{b}}{ρ} )} {V}_{X}$$

represents a threshold singular value decomposition operation of matrix X∈ [symbol] ^{X}^{₁}^{×X}^{₂},

$${Σ}_{( \frac{{α}_{b}}{ρ} )} = diag ( max ( {\overline{ω}}_{l} - \frac{{α}_{b}}{ρ} , 0 ) ) ,$$

ω̅ₗ, l=1, 2, . . . , min (X₁, X₂) represents the singular value of X, Uₓ, Vₓ represent the left and right singular matrices of X, fold_{(b)}[⋅] represents an inverse operation of tensor expansion [⋅]_{(b)}, diag(c) represents a diagonal matrix with the elements in the vector c as diagonal elements, max(⋅) represents a maximum operation, min(⋅) represents a minimum operation. Through the iteration of the alternating direction method of multipliers, the filled structured virtual domain tensor [symbol] is obtained;
Step 7: decomposing the filled structured virtual domain tensor to achieve super-resolution spatial spectrum estimation. Theoretical modeling the filled structured virtual domain tensor [symbol] as:

$${\overline{𝒦}}_{\overline{ℚ}} = {\sum }_{k = 1}^{K} {σ}_{k}^{2} p ( {μ}_{k} , {v}_{k} ) ∘ q ( {μ}_{k} , {v}_{k} ) ∘ c ( {μ}_{k} , {v}_{k} ) ,$$

wherein, p(μₖ, νₖ)=dₓ(μₖ)⊗d_{y}(νₖ), q(μₖ, νₖ)=gₓ(μₖ)⊗g_{y}(νₖ) are spatial factors of

[symbol]

$${d}_{x} ( {μ}_{k} ) = {[ {e}^{- j π ( - {M}_{x} {N}_{x} + {M}_{x} ) {μ}_{k}} , {e}^{- j π ( - {M}_{x} {N}_{x} + {M}_{x} + 1 ) {μ}_{k}} , … , {e}^{- j π ( 2 {M}_{x} {N}_{x} - {N}_{x} ) {μ}_{k}} ]}^{T} , \\ {d}_{y} ( {v}_{k} ) = {[ {e}^{- j π ( - {M}_{y} {N}_{y} + {M}_{y} ) {v}_{y}} , {e}^{- j π ( - {M}_{y} {N}_{y} + {M}_{y} + 1 ) {v}_{k}} , … , {e}^{- j π ( 2 {M}_{y} {N}_{y} - {N}_{y} ) {v}_{k}} ]}^{T} ,$$

represent the steering vectors of the virtual uniform cubic array [symbol] along the x axis direction and the y axis direction respectively,

$${g}_{x} ( {μ}_{k} ) = {[ 1 , {e}^{- j {πμ}_{k}} , … , {e}^{- j π ( {L}_{x} - 1 ) {μ}_{k}} ]}^{T} , \\ {g}_{y} ( {v}_{k} ) = {[ 1 , {e}^{- j π {v}_{k}} , … , {e}^{- j π ( {L}_{y} - 1 ) {v}_{k}} ]}^{T} ,$$

are the space translation factor vectors corresponding to the x axis direction and the y axis direction in the process of the translation window intercepting the virtual domain sub-tensor. Performing a canonical polyadic decomposition on the filled structured virtual domain tensor [symbol] , so as to obtain the estimated values of three factor vectors p(μₖ, νₖ), q(μₖ, νₖ) and c(μₖ, νₖ), representing as \hat{p}(μₖ, νₖ), \hat{q}(μₖ, νₖ) and ĉ(μₖ, νₖ). Constructing a structured virtual domain tensor signal sub-space Vₛ∈ [symbol] ^{2P}^{ₓ}^{P}^{_{y}}^{L}^{ₓ}^{L}^{_{y}}^{×K}:

$${V}_{s} = orth ( [ \hat{p} ( {μ}_{1} , {v}_{1} ) ⊗ \hat{q} ( {μ}_{1} , {v}_{1} ) ⊗ \hat{c} ( {μ}_{1} , {v}_{1} ) , \\ \hat{p} ( {μ}_{2} , {v}_{2} ) ⊗ \hat{q} ( {μ}_{2} , {v}_{2} ) ⊗ \hat{c} ( {μ}_{2} , {v}_{2} ) , … , \hat{p} ( {μ}_{K} , {v}_{K} ) ⊗ \hat{q} ( {μ}_{K} , {v}_{K} ) ⊗ \hat{c} ( {μ}_{K} , {v}_{K} ) ] ) ,$$

wherein, orth(⋅) represents a matrix orthogonalization operation; representing the noise sub-space as Vₙ∈ [symbol] ^{2P}^{ₓ}^{P}^{_{y}}^{L}^{ₓ}^{L}^{_{y}}^{×(2P}^{ₓ}^{P}^{_{y}}^{L}^{ₓ}^{L}^{_{y}}^{-K}), VₙVₙ^{H} is obtained by Vₛ:

$${V}_{n} {V}_{n}^{H} = I - {V}_{s} {V}_{s}^{H} ,$$

wherein, I represents the identity matrix, (⋅)^{H} represents a conjugate transpose operation.

Traversing the two-dimensional arrival direction of wave (θ, φ), and calculating the corresponding parameters μₖ=sin (φₖ) cos (θₖ), νₖ=sin (φₖ) sin (θₖ), and constructing the steering vector [symbol] (μₖ, νₖ)∈ [symbol] ^{2P}^{ₓ}^{P}^{_{y}}^{L}^{ₓ}^{L}^{_{y}} corresponding to the virtual uniform cubic array [symbol] , expressed as:

$$𝓋 ( {μ}_{k} , {v}_{k} ) = \hat{p} ( {μ}_{k} , {v}_{k} ) ⊗ \hat{q} ( {μ}_{k} , {v}_{k} ) ⊗ \hat{c} ( {μ}_{k} , {v}_{k} ) ,$$

Here, θ∈[−90°, 90°], φ∈[0°, 180°]. obtaining the spatial spectrum [symbol] (θ, φ) corresponding to the two-dimensional arrival direction of wave (θ, φ) as follows:

$$𝒫 ( θ , φ ) = 1 / ( {𝓋}^{H} ( {μ}_{k} , {v}_{k} ) ( {V}_{n} {V}_{n}^{H} ) 𝓋 ( {μ}_{k} , {v}_{k} ) ) .$$

The effects of the present invention will be further described below in conjunction with a simulation instance.

The simulation instance: The coprime planar array is used to receive the incident signal, and its parameters are selected as Mₓ=2, M_{y}=3, Nₓ=3, and N_{y}=4, that is, the constructed coprime planar array contains 4MₓM_{y}+NₓN_{y}−1=35 physical array elements. Assuming that there are 2 narrowband incident signals, the azimuth and elevation angles of the incident directions are respectively [35°, 20°] and [45.5°, 40.5°]. According to the dimension optimization problem of the virtual domain sub-tensor mentioned in the present invention, the optimal virtual domain sub-tensor dimension is obtained as 7×14×2, and the corresponding dimension of the optimal structured virtual domain tensor [symbol] is 56×238×2. The kernel norm weight constant of [symbol] is taken as α₁=α₂=α₃=⅓.

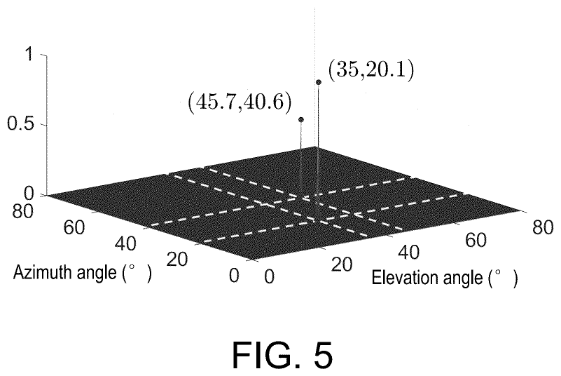

Under the condition of SNR=0 dB, the simulation experiment is carried out with 300 sampling snapshots. The normalized spatial spectrum estimation results corresponding to the method of the present invention are as shown in FIG. 5, wherein the x axis and y axis respectively represent the azimuth and elevation angles of the incident signal source. It can be seen that the method of the present invention can form a precise sharp spectral peak in the position of the corresponding wave arrival direction of the two incident signal sources, which indicates the excellent performance of the proposed spatial spectrum estimation method in terms of accuracy and resolution.

The above descriptions are only preferred embodiments of the present invention. Although the present invention has been disclosed above with preferred examples, it is not intended to limit the present invention. Any person skilled in the art, without departing from the scope of the technical solution of the present invention, can make many possible changes and modifications to the technical solution of the present invention by using the methods and technical contents disclosed above, or modify them into equivalent examples of equivalent changes. Therefore, any simple alterations, equivalent changes and modifications made to the above embodiments according to the technical essence of the present invention without departing from the content of the technical solutions of the present invention still fall within the protection scope of the technical solutions of the present invention.

1. A space spectrum estimation method of a super-resolution coprime planar array based on tensor filling of an optimal structured virtual domain, wherein the method comprises the following steps:
(1) by using 4MₓM_{y}+NₓN_{y}−1 physical antenna array elements, performing construction by a receiving end according to the structure of the coprime planar array, wherein, Mₓ, Nₓ and M_{y}, N_{y} are a pair of coprime integers respectively; the coprime planar array is decomposed into two sparse uniform sub-planar arrays [symbol] ₁ and [symbol] ₂, wherein [symbol] ₁ contains 2Mₓ×2M_{y} antenna array elements, and array element spacings in an x axis direction and a y axis direction are Nₓd and N_{y}d respectively; and [symbol] 2 contains Nₓ×N_{y} antenna array elements, and array element spacings in the x axis direction and the y axis direction are Mₓd and M_{y}d respectively; an unit interval d is half of a wavelength λ of an incident narrowband signal, i.e. d=λ/2;
assuming there are K far-field narrow-band incoherent signal sources from {(θ₁, φ₁), (θ₂, φ₂), . . . , (θ_{K}, φ_{K})} directions, and θₖ and φₖ are azimuth and elevation angles of a kth incident signal source respectively, k=1, 2, . . . , K, then T sampling snapshot signals of the sparse uniform sub-planar array [symbol] ₁ can be expressed b_{y} a three-dimensional tensor χ [symbol] _{₁} ∈ [symbol] ^{2M}^{ₓ}^{×2M}^{_{y}}^{×T} as follows:
$${𝒳}_{{ℙ}_{1}} = {\sum }_{k = 1}^{K} {a}_{x}^{( {ℙ}_{1} )} ( {θ}_{k} , {φ}_{k} ) ∘ {a}_{y}^{( {ℙ}_{1} )} ( {θ}_{k} , {φ}_{k} ) ∘ {s}_{k} + {𝒩}_{{ℙ}_{1}} ,$$
wherein, sₖ=[S_{k,1}, S_{k,2}, . . . , S_{k,T}]^{T} is a multi-snapshot sampling signal waveform corresponding to a kth incident signal source, [⋅]^{T} represents a transpose operation, · represents an outer product of the vectors, [symbol] is a noise tensor independent of each signal source, [symbol] (θₖ, φₖ) and [symbol] (θₖ, φₖ) are steering vectors of [symbol] ₁ in the x axis direction and the y axis direction respectively, and correspond to a signal source with an arrival direction of wave being (θₖ, φₖ), and are expressed as:
$$\begin{matrix}{a}_{x}^{( {ℙ}_{1} )} ( {θ}_{k} , {φ}_{k} ) = {[ 1 , {e}^{- j π {x}_{{ℙ}_{1}}^{( 2 )} {μ}_{k}} , … , {e}^{- j π {x}_{{ℙ}_{1}}^{( 2 {M}_{x} )} {μ}_{k}} ]}^{T} , \\ {a}_{y}^{( {ℙ}_{1} )} ( {θ}_{k} , {φ}_{k} ) = {[ 1 , {e}^{- j π {y}_{{ℙ}_{1}}^{( 2 )} {v}_{k}} , … , {e}^{- j π {y}_{{ℙ}_{1}}^{( 2 {M}_{y} )} {v}_{k}} ]}^{T} ,\end{matrix}$$
wherein, { [symbol] . . . , [symbol] } and { [symbol] . . . , [symbol] } respectively represent actual positions of the physical antenna array elements of the sparse uniform sub-planar array [symbol] ₁ in the x axis direction and they axis direction, and [symbol] =0, [symbol] =0, μₖ=sin (φₖ) cos (θₖ), νₖ=sin (φₖ) sin (θₖ), j=\sqrt{−1};
a received signal of the sparse uniform sub-planar array [symbol] ₂ is represented by another three-dimensional tensor [symbol] ∈ [symbol] ^{N}^{ₓ}^{×N}^{_{y}}^{×T}:
$${X}_{{ℙ}_{2}} D = {\sum }_{k = 1}^{K} {a}_{x}^{( {ℙ}_{2} )} ( {θ}_{k} , {φ}_{k} ) ∘ {a}_{y}^{( {ℙ}_{2} )} ( {θ}_{k} , {φ}_{k} ) ∘ {s}_{k} + {𝒩}_{{ℙ}_{2}} ,$$
wherein, [symbol] is a noise tensor independent of each signal source, [symbol] (θₖ, φₖ) and [symbol] (θₖ, φₖ) are steering vectors of [symbol] ₂ in the x axis direction and the y axis direction respectively, and correspond to a signal source with an arrival direction of wave being (θₖ, φₖ), and are expressed as:
$$\begin{matrix}{a}_{x}^{( {ℙ}_{2} )} ( {θ}_{k} , {φ}_{k} ) = {[ 1 , {e}^{- j π {x}_{{ℙ}_{2}}^{( 2 )} {μ}_{k}} , … , {e}^{- j π {x}_{{ℙ}_{2}}^{( 2 {N}_{x} )} {μ}_{k}} ]}^{T} , \\ {a}_{y}^{( {ℙ}_{2} )} ( {θ}_{k} , {φ}_{k} ) = {[ 1 , {e}^{- j π {y}_{{ℙ}_{2}}^{( 2 )} {v}_{k}} , … , {e}^{- j π {y}_{{ℙ}_{2}}^{( 2 {N}_{y} )} {v}_{k}} ]}^{T} ,\end{matrix}$$
wherein, { [symbol] . . . , [symbol] } and { [symbol] . . . , [symbol] } respectively represent actual positions of the physical antenna array elements of the sparse uniform sub-planar array [symbol] ₂ in the x axis direction and the y axis direction, and [symbol] =0, [symbol] =0;
(2) by solving cross-correlation statistics of tensors [symbol] and [symbol] , obtaining a second-order cross-correlation tensor [symbol] ∈ [symbol] ^{2M}^{ₓ}^{×2M}^{_{y}}^{×N}^{ₓ}^{×N}^{_{y}}:
$$\begin{matrix}{ℛ}_{{ℙ}_{1} {ℙ}_{2}} = E [ < {𝒳}_{{ℙ}_{1}} , {𝒳}_{{ℙ}_{2}}^{*} {>}_{3} ] \\ = {\sum }_{k = 1}^{K} {σ}_{k}^{2} {a}_{x}^{( {ℙ}_{1} )} ( {θ}_{k} , {φ}_{k} ) ∘ {a}_{y}^{( {ℙ}_{1} )} ( {θ}_{k} , {φ}_{k} ) ∘ {a}_{x}^{{( {ℙ}_{2} )}^{*}} ( {θ}_{k} , {φ}_{k} ) ∘ {a}_{y}^{{( {ℙ}_{2} )}^{*}} ( {θ}_{k} , {φ}_{k} ) + {𝒩}_{{ℙ}_{1} {ℙ}_{2}} ,\end{matrix}$$
wherein, σₖ²=E[sₖsₖ^{*}] represents the power of a kth incident signal source, [symbol] =E[< [symbol] >₃] represents a cross-correlation noise tensor, <⋅, ⋅>ᵣ represents a tensor contraction operation of two tensors along an rth dimension, E[⋅] represents a mathematical expectation operation, and (⋅)* represents a conjugated operation; defining two dimensional sets [symbol] ={1, 3} and [symbol] ={2, 4}, then a virtual domain signal [symbol] ∈ [symbol] ^{2M}^{ₓ}^{N}^{ₓ}^{×2M}^{_{y}}^{N}^{_{y}} is obtained by combination the dimensions of the cross-correlation tensor [symbol] :
$${U}_{𝕎} {=}^{△} {ℛ}_{{ℙ}_{1} {ℙ}_{{2}_{\{ {𝕁}_{1} , {𝕁}_{2} \}}}} = {\sum }_{k = 1}^{K} {σ}_{k}^{2} {b}_{x} ( k ) ∘ {b}_{y} ( k ) ,$$
wherein, bₓ(k)= [symbol] (θₖ, φₖ) ⊗ [symbol] (θₖ, φₖ) and b_{y}(k)= [symbol] (θₖ, φₖ)⊗ [symbol] (θₖ, φₖ) are respectively equivalent to steering vectors of a discontinuous virtual planar array in the [symbol] axis direction and the y axis direction, corresponding to a signal source of which the arrival direction of wave is (θₖ, φₖ), and ⊗ represents the Kronecker product; the discontinuous virtual planar array [symbol] has a size of [symbol] × [symbol] , and contains holes of a whole row and a whole column, [symbol] =3MₓNₓ−Mₓ−Nₓ+1, [symbol] =3M_{y}N_{y}−M_{y}−N_{y}+1;
(3) constructing a virtual planar array [symbol] about a coordinate axis mirror of the discontinuous virtual planar array [symbol] , and superimposing [symbol] and [symbol] in a third dimension into a three-dimensional discontinuous virtual cubic array [symbol] of size [symbol] wherein [symbol] = [symbol] = [symbol] , and [symbol] =2; rearranging elements in a conjugate transpose signal [symbol] of the virtual domain signal [symbol] to correspond to a position of each virtual element in [symbol] , so as to correspond to a virtual domain signal [symbol] corresponding to the virtual planar array [symbol] ; superimposing [symbol] and [symbol] in the third dimension to obtain a virtual domain tensor [symbol] of the corresponding discontinuous virtual cubic array [symbol] , expressed as:
$${𝒰}_{ℚ} = {\sum }_{k = 1}^{K} {σ}_{k}^{2} {\tilde{b}}_{x} ( k ) ∘ {\tilde{b}}_{y} ( k ) ∘ c ( {μ}_{k} , {v}_{k} ) ,$$
wherein, \tilde{b}ₓ(k) and \tilde{b}_{y}(k) are steering vectors of the discontinuous virtual cubic array [symbol] in the x axis direction and the y axis direction respectively, corresponding to a signal source of which an arrival direction of wave is (θₖ, φₖ), and the elements in \tilde{b}ₓ(k) and \tilde{b}_{y}(k) corresponding to the hole positions in the x axis direction and y axis direction in [symbol] are set to zero respectively,
$$c ( {μ}_{k} , {v}_{k} ) = {[ 1 , {e}^{- j π ( - ( {M}_{x} {M}_{y} + {M}_{x} + {M}_{y} ) {μ}_{k} - ( {N}_{x} {N}_{y} + {N}_{x} + {N}_{y} ) {v}_{k} )} ]}^{T}$$
represents mirror transformation factor vectors corresponding to [symbol] and [symbol] ; since the discontinuous virtual planar array [symbol] contains the whole row and the whole column of holes, the discontinuous virtual cubic array [symbol] obtained by superposition of [symbol] and mirror part [symbol] thereof contains pieces of missing elements, namely holes, so the corresponding virtual domain tensor [symbol] contains pieces of zero elements;
(4) intercepting a virtual domain sub-tensor [symbol] of the virtual domain tensor [symbol] through a translation window with a size of Pₓ×P_{y}×2, wherein [symbol] contains elements of which indexes are respectively (1:Pₓ−1), (1:P_{y}−1), (1:2) in three dimensions of [symbol] ; then, translating the translation window with one element in turn along the x axis direction and the y axis direction respectively, and dividing [symbol] into Lₓ×L_{y} virtual domain sub-tensors, expressed as
$${𝒰}_{{ℚ}_{( {s}_{x} , {s}_{y} )}} ,$$
sₓ=1, 2, . . . , Lₓ, s_{y}=1, 2, . . . , L_{y}; the value range of the translation window size is:
$$2 \leq {P}_{x} \leq {J}_{{ℚ}_{x}} - 1 , 2 \leq {P}_{y} \leq {J}_{{ℚ}_{y}} - 1 ,$$
and Lₓ, L_{y}, Pₓ, P_{y} satisfy the following relation:
$${P}_{x} + {L}_{x} - 1 = {J}_{{ℚ}_{x}} , {P}_{y} + {L}_{y} - 1 = {J}_{{ℚ}_{y}} ,$$
superimposing, in a fourth dimension, the virtual domain sub-tensors
$${𝒰}_{{ℚ}_{( {s}_{x} , {s}_{y} )}}$$
with the same index subscript of s_{y} to obtain L_{y} four-dimensional tensors with dimensions of Pₓ×P_{y}×2×Lₓ; further, superimposing, in a fifth dimension, the L_{y} four-dimensional tensors to obtain a five-dimensional virtual domain tensor [symbol] ∈ [symbol] ^{P}^{ₓ}^{×P}^{_{y}}^{×2×L}^{ₓ}^{×L}^{_{y}}, which contains spatial angle information in the x axis direction and the y axis direction, spatial mirror transformation information, and spatial translation information in the x axis direction and the y axis direction; defining dimension sets [symbol] ₁={1, 2}, [symbol] ₂={3}, [symbol] ₃={4, 5}, and then transforming the virtual domain tensor for dimension combination of [symbol] to obtain a three-dimensional structured virtual domain tensor [symbol] ∈ [symbol] ^{P}^{ₓ}^{P}^{_{y}}^{×L}^{ₓ}^{L}^{_{y}}^{×2}:
$${𝒦}_{ℚ} {=}^{△} {𝒯}_{{ℚ}_{\{ {𝕂}_{1} , {𝕂}_{2} , {𝕂}_{3} \}}} ,$$
three dimensions of [symbol] respectively represent spatial angle information, spatial translation information, and spatial mirror transformation information; therefore, pieces of missing elements in the virtual domain tensor [symbol] are randomly distributed to the three spatial dimensions contained by the structured virtual domain tensor [symbol] ;
(5) since dispersion degree and proportion of the zero elements in the structured virtual domain tensor [symbol] are closely related to the effect of tensor filling, in order to ensure the maximum dispersion degree and minimum proportion of the zero elements in [symbol] , optimizing the dimension size of the virtual domain sub-tensor, that is, optimizing and selecting the value of (Pₓ, P_{y}), so as to obtain an optimal structured virtual domain tensor, wherein a specific process is as follows: according to each value combination (Pₓ, P_{y}), calculating a sum of Euclidean distances of each two zero elements in the corresponding structured virtual domain tensor [symbol] :
$$ψ = {\sum }_{{ζ}_{{z}_{1}} , {ζ}_{{z}_{1}} ∈ Ω , {ζ}_{{z}_{1}} \neq {ζ}_{{z}_{1}}} {‖ {ζ}_{{z}_{1}} - {ζ}_{{z}_{2}} ‖}_{2} ,$$
wherein, Ω represents a position index set of zero elements in [symbol] , ζ_{Z}_{₁} and ζ_{Z}_{₂} represent the coordinates of any two positions in the set Ω, wherein, z₁, z₂=1, 2, . . . , [symbol] represents the total number of zero elements in [symbol] ; the dispersion degree of zero elements in the structured virtual domain tensor [symbol] is determined by parameter ψ; correspondingly, expressing the proportion of zero elements in the structured virtual domain tensor [symbol] as:
$${z}_{} = \frac{{Z}_{{𝒦}_{ℚ}}}{2 {P}_{x} {P}_{y} {L}_{x} {L}_{y}} ,$$
comprehensively considering maximizing the dispersion degree of zero elements in the structured virtual domain tensor and minimizing the proportion of zero elements [symbol] _{z}, expressing a dimension optimization problem of the virtual domain sub-tensor as:
$${min}_{{P}_{x} , {P}_{y}} ψ / {z}_{} \\ \begin{matrix}s . t . 2 \leq {P}_{x} \leq {J}_{{ℚ}_{x}} - 1 , \\ 2 \leq {P}_{y} \leq {J}_{{ℚ}_{y}} - 1 ,\end{matrix}$$
traversing all values within the value range [2, [symbol] −1] and [2, [symbol] −1] of Pₓ and P_{y}, the values of each group (Pₓ, P_{y}) correspond to the values of a group (Pₓ, P_{y}) corresponding to the objective function value ψ/ [symbol] _{z}, which is selected as the maximum value of the target function, that is, the dimension size of the optimal virtual domain sub-tensor
$${𝒰}_{{ℚ}_{( {s}_{x} , {s}_{y} )}} ;$$
(6) designing a structured virtual domain tensor filling optimization problem based on an alternating direction method of multipliers:
$${min}_{{\overline{𝒦}}_{\overline{ℚ}} , {𝒴}_{b}} {\sum }_{b = 1}^{3} {α}_{b} {‖ {[ {\overline{𝒦}}_{\overline{ℚ}} ]}_{( b )} ‖}_{*} s . t . {𝒫}_{\overline{Ω}} ( {\overline{𝒦}}_{\overline{ℚ}} ) = {𝒫}_{\overline{Ω}} ( {𝒦}_{ℚ} ) ,$$
$${𝒴}_{b} - {\overline{𝒦}}_{\overline{ℚ}} = 𝒪 ,$$
wherein, an optimization variable [symbol] ∈ [symbol] ^{P}^{ₓ}^{P}^{_{y}}^{×L}^{ₓ}^{L}^{_{y}}^{×2} is the filled structured virtual domain tensor, corresponding to a virtual uniform cubic array [symbol] ; [ [symbol] ]_{(b)} represents a matrix expanded by [symbol] along the bth dimension; α_{b} is a kernel norm weight constant, which needs to meet α₁+α₂+α₃=1; ∥⋅∥_{*} represents the kernel norm; in order to ensure that the kernel norms [ [symbol] ]_{(b)} of the three matrices of [symbol] can be optimized independently, the three auxiliary tensors [symbol] _{b}= [symbol] , b=1, 2, 3 of [symbol] are introduced in this problem; ψ̅ represents the position index set of non-zero elements in [symbol] ; [symbol] _{ψ̅} (⋅) represents the mapping of the tensor on ψ̅; [symbol] represents the zero tensor; introducing a dual variable [symbol] _{b}, b=1, 2, 3 of [symbol] _{b}, then the Lagrange function of the above optimization problem can be expressed as:
$$ℒ ( {\overline{𝒦}}_{\overline{ℚ}} , {𝒴}_{b} , {ℳ}_{b} ) = ‖ {\overline{𝒦}}_{\overline{ℚ}} {‖}_{*} + [ {𝒴}_{b} - {\overline{𝒦}}_{\overline{ℚ}} \times {ℳ}_{b} ] + \frac{ρ}{2} {‖ {𝒴}_{b} - {\overline{𝒦}}_{\overline{ℚ}} ‖}_{F}^{2} ,$$
wherein, ρ>0 is a compensation factor, [⋅x⋅] is a tensor inner product, ∥⋅∥_{F} represents the Frobenius norm; iteratively solving a target variable [symbol] , [symbol] _{b} b_{y} minimizing the Lagrange function, so as to obtain the filled structured virtual domain tensor [symbol] ;
(7) theoretical modeling the filled structured virtual domain tensor [symbol] as:
$${\overline{𝒦}}_{\overline{ℚ}} = {\sum }_{k = 1}^{K} {σ}_{k}^{2} p ( {μ}_{k} , {v}_{k} ) ∘ q ( {μ}_{k} , {v}_{k} ) ∘ c ( {μ}_{k} , {v}_{k} ) ,$$
wherein, p(μₖ, νₖ)=dₓ(μₖ)⊗d_{y}(νₖ), q(μₖ, νₖ)=gₓ(μₖ)⊗g_{y}(νₖ) are spatial factors of [symbol] ,
$${d}_{x} ( {μ}_{k} ) = {[ {e}^{- j π ( - {M}_{x} {N}_{x} + {M}_{x} ) {μ}_{k}} , {e}^{- j π ( - {M}_{x} {N}_{x} + {M}_{x} + 1 ) {μ}_{k}} , … , {e}^{- j π ( 2 {M}_{x} {N}_{x} - {N}_{x} ) {μ}_{k}} ]}^{T} ,$$
$${d}_{y} ( {v}_{k} ) = {[ {e}^{- j π ( - {M}_{y} {N}_{y} + {M}_{y} ) {v}_{k}} , {e}^{- j π ( - {M}_{y} {N}_{y} + {M}_{y} + 1 ) {v}_{k}} , … , {e}^{- j π ( 2 {M}_{y} {N}_{y} - {N}_{y} ) {v}_{k}} ]}^{T} ,$$
represent the steering vectors of the virtual uniform cubic array [symbol] along the x axis direction and the y axis direction respectively,
$${g}_{x} ( {μ}_{k} ) = {[ 1 , {e}^{- j {πμ}_{k}} , … , {e}^{- j π ( {L}_{x} - 1 ) {μ}_{k}} ]}^{T} ,$$
$${g}_{y} ( {v}_{k} ) = {[ 1 , {e}^{- j π {v}_{k}} , … , {e}^{- j π ( {L}_{y} - 1 ) {v}_{k}} ]}^{T} ,$$
are the spatial translation factor vectors corresponding to the x axis direction and the y axis direction in the process of the translation window intercepting the virtual domain sub-tensor respectively; performing a canonical polyadic decomposition on the filled structured virtual domain tensor [symbol] , so as to obtain estimated values of three factor vectors p(μₖ, νₖ), q(μₖ, νₖ) and c(μₖ, νₖ), representing as \hat{p}(μₖ, νₖ), \hat{q}(μₖ, νₖ) and ĉ(μₖ, νₖ); constructing a structured virtual domain tensor signal sub-space Vₛ∈ [symbol] ^{2P}^{ₓ}^{P}^{_{y}}^{L}^{ₓ}^{L}^{_{y}}^{×K}:
$${V}_{s} = orth ( [ \hat{p} ( {μ}_{1} , {v}_{1} ) ⊗ \hat{q} ( {μ}_{1} , {v}_{1} ) ⊗ \hat{c} ( {μ}_{1} , {v}_{1} ) , \hat{p} ( {μ}_{2} , {v}_{2} ) ⊗ \hat{q} ( {μ}_{2} , {v}_{2} ) ⊗ \hat{c} ( {μ}_{2} , {v}_{2} ) , … , \hat{p} ( {μ}_{K} , {v}_{K} ) ⊗ \hat{q} ( {μ}_{K} , {v}_{K} ) ⊗ \hat{c} ( {μ}_{K} , {v}_{K} ) ] ) ,$$
wherein, orth(⋅) represents a matrix orthogonalization operation; representing the noise sub-space as Vₙ ∈ [symbol] ^{2P}^{ₓ}^{P}^{_{y}}^{L}^{ₓ}^{L}^{_{y}}^{×(2P}^{ₓ}^{P}^{_{y}}^{L}^{ₓ}^{L}^{_{y}}^{-K}), whereby VₙVₙ^{H} is obtained by Vₛ through the following formula:
$${V}_{n} {V}_{n}^{H} = 1 - {V}_{s} {V}_{s}^{H} ,$$
wherein, I represents an identity matrix, (⋅)^{H} represents a conjugate transpose operation;
traversing a two-dimensional arrival direction of wave (θ, φ), wherein θ and φ are respectively azimuth angle and elevation angle traversed within the value range of [−90°, 90°] and [0°, 180°], calculating the corresponding parameters μk=sin (φₖ) cos (θₖ), νₖ=sin (φₖ) sin (θₖ), and constructing the steering vector [symbol] (μₖ, νₖ)∈ [symbol] ^{2P}^{ₓ}^{P}^{_{y}}^{L}^{ₓ}^{L}^{_{y}} corresponding to the virtual uniform cubic array [symbol] expressed as:
$$( {μ}_{k} , {v}_{k} ) = \hat{p} ( {μ}_{k} , {v}_{k} ) ⊗ \hat{q} ( {μ}_{k} , {v}_{k} ) ⊗ \hat{c} ( {μ}_{k} , {v}_{k} ) ,$$
obtaining the spatial spectrum [symbol] (θ, _{φ}) corresponding to the two-dimensional arrival direction of wave (θ, _{φ}) as follows:
$$𝒫 ( θ , φ ) = 1 / ( {H}^{} ( {μ}_{k} , {v}_{k} ) ( {V}_{n} {V}_{n}^{H} ) ( {μ}_{k} , {v}_{k} ) ) .$$

2. The space spectrum estimation method of the super-resolution coprime planar array based on tensor filling of the optimal structured virtual domain according to claim 1, wherein the structure of the coprime planar array described in step (1) is specifically described as follows: constructing a pair of sparse uniform sub-planar arrays [symbol] ₁ and [symbol] ₂ on the plane coordinate system xoy, wherein, [symbol] ₁ contains 2Mₓ×2M_{y} antenna array elements, the array element spacings in the x axis direction and the y axis direction are Nₓd and N_{y}d respectively, and the position coordinate thereof on xoy is {(Nₓdmₓ, N_{y}dm_{y}), mₓ=0, 1, . . . , 2Mₓ−1, m_{y}=0, 1, . . . , 2M_{y}−1}; [symbol] ₂ contains Nₓ×N_{y} antenna array elements, the array spacings in the x axis direction and the y axis direction are Mₓd and M_{y}d respectively, and the position coordinate thereof on xoy is {(Mₓdnₓ, M_{y}dn_{y}), nₓ=0, 1, . . . , Nₓ−1, n_{y}=0, 1, . . . , N_{y}−1}; Mₓ, Nₓ and M_{y}, N_{y} are a pair of reciprocal integers, respectively; performing a sub-array combination on [symbol] ₁ and [symbol] ₂ in the way of overlapping the array elements in (0, 0) position in the coordinate system, whereby a coprime planar array containing 4MₓM_{y}+NₓN_{y}−1 physical antenna array elements is obtained.

3. The space spectrum estimation method of the super-resolution coprime planar array based on tensor filling of the optimal structured virtual domain according to claim 1, wherein in the cross-correlation tensor deduction described in step (2), in practice, [symbol] is obtained by estimating the cross-correlation statistics of the tensors [symbol] and [symbol] , namely, sampling the cross-correlation tensor [symbol] ∈ [symbol] ^{2M}^{ₓ}^{×2M}^{_{y}}^{×N}^{ₓ}^{×N}^{_{y}}:
$${\hat{ℛ}}_{{ℙ}_{1} {ℙ}_{2}} = \frac{1}{T} {〈 {𝒳}_{{ℙ}_{1}} , {𝒳}_{{ℙ}_{2}}^{*} 〉}_{3} .$$

4. The space spectrum estimation method of the super-resolution coprime planar array based on tensor filling of the optimal structured virtual domain according to claim 1, wherein in step (6), the target variables [symbol] , [symbol] are iteratively solved by minimizing the Lagrange function [symbol] ( [symbol] , [symbol] _{b}, [symbol] _{b}); in the η+1th iteration, [symbol] , [symbol] _{b} and [symbol] _{b} are updated as:
$${𝒴}_{b}^{( η + 1 )} = {arg min}_{{𝒴}_{b}} ℒ ( {\overline{𝒦}}_{\overline{ℚ}}^{( η )} , {𝒴}_{b} , {ℳ}_{b}^{( η )} ) ,$$
$${\overline{𝒦}}_{\overline{ℚ}}^{( η + 1 )} = {arg min}_{{\overline{𝒦}}_{\overline{ℚ}}} ℒ ( {\overline{𝒦}}_{\overline{ℚ}} , {𝒴}_{b}^{( η + 1 )} , {ℳ}_{b}^{( η )} ) ,$$
$${ℳ}_{b}^{( η + 1 )} = {ℳ}_{b}^{( η )} - ρ ( {𝒴}_{b}^{( η + 1 )} - {\overline{𝒦}}_{\overline{ℚ}}^{( η + 1 )} ) ,$$
a closed-form solution for the target variables [symbol] , [symbol] _{b} are as follows:
$${𝒴}_{b}^{( η + 1 )} = {fold}_{( b )} [ {Γ}_{\frac{{α}_{b}}{ρ}} ( {[ {\overline{𝒦}}_{\overline{ℚ}}^{( η )} ]}_{( b )} + {\frac{1}{ρ} [ {ℳ}_{b}^{( η + 1 )} ]}_{( b )} ) ] ,$$
$${𝒫}_{Ω} ( {\overline{𝒦}}_{\overline{ℚ}}^{( η + 1 )} ) = {𝒫}_{Ω} ( \frac{1}{3} ( {\sum }_{b = 1}^{3} {𝒴}_{b}^{( η + 1 )} - \frac{1}{ρ} {ℳ}_{b}^{( η )} ) ) ,$$
wherein,
$${Γ}_{\frac{{α}_{b}}{ρ}} ( X ) = {U}_{X} {\sum }_{( \frac{{α}_{b}}{ρ} )} {V}_{X}$$
represents a threshold singular value decomposition operation of matrix
$$X ∈ {ℂ}^{{X}_{1} \times {X}_{2}} ,$$
$${\sum }_{( \frac{{α}_{b}}{ρ} )} = diag ( max ( {ϖ}_{1} - \frac{{α}_{b}}{ρ} , 0 ) ) ,$$
ω̅ₗ, l=1, 2, . . . , min (X₁, X₂) represents the singular value of X, Uₓ, Vₓ represent the left and right singular matrices of X, fold_{(b)}[⋅] represents an inverse operation of tensor expansion [⋅]_{(b)}, diag(c) represents a diagonal matrix with the elements in the vector c as diagonal elements, max(⋅) represents a maximum operation, min(⋅) represents a minimum operation.
